(19) United States
(12) Patent Application Publication
(10) Pub. No.: US 2013/0140541 A1
(43) Pub. Date: Jun. 6, 2013

(54) LAYER STRUCTURE COMPRISING ELECTROTECHNICAL COMPONENTS

(71) Applicants: Rainer Kunz, Holzappel (DE); Wilfried Hedderich, Hilden (DE); Carsten Benecke, Weil am Rhein (DE)

(72) Inventors: Rainer Kunz, Holzappel (DE); Wilfried Hedderich, Hilden (DE); Carsten Benecke, Weil am Rhein (DE)

(73) Assignee: Bayer Intellectual Property GmbH, Moneheim (DE)

(21) Appl. No.: 13/703,143

(22) PCT Filed: Jun. 7, 2011
(86) PCT No.: PCT/EP2011/059383

§ 371 Date: Feb. 8, 2013

(30) Foreign Application Priority Data
Jun. 10, 2010 (EP) 1016581.9

(51) Int. Cl. H01L 27/32; H01L 51/56

(52) U.S. Cl. CPC H01L 27/3225; H01L 51/56
USPC 257/40; 438/23

(57) ABSTRACT

The present invention provides a layer structure comprising a substrate (1), at least one LEC (7) (light emitting electrochemical cell) and at least one further electrotechnical structural element (4, 5, 8), a process for the production of this layer structure, and the use thereof in the production of small and large display and control elements and in the production of casing elements for mobile or stationary electronic devices or small or large household appliances or in the production of keyboard systems without moving components.

The present invention provides a layer structure comprising a substrate, at least one LEC (light emitting electrochemical cell) and at least one further electrotechnical structural element, a process for the production of this layer structure, and the use thereof in the production of small and large display and control elements and in the production of casing elements for mobile or stationary electronic devices or small or large household appliances or in the production of keyboard systems without moving components.

In many areas of technology, an electrical or electronic device needs to be provided with the component “light”, that is to say with illumination or with a display. This can be, for example, the backlighting of a switch, which indicates the location and/or the on/off state of the switch, or it can be the display of a mobile telephone, which illuminates when the antenna of the mobile telephone receives a signal. It is also to be possible to provide other electrotechnical structural elements, apart from switches or antennae, with illumination. The component “light” is preferably to be made available using an electrically operated lamp or display.

In addition, it is necessary to be able to operate such an electrical or electronic device independently of the location and even in darkness. This means that it must contain a battery or an accumulator, but it should also be possible to connect it to a higher-voltage power supply, for example to the battery of the device comprising the layer structure, for example an independent operating console of a motor vehicle, to the battery of the product, for example of a motor vehicle, in which the device is fitted, to the national grid when the layer structure is fitted into a household appliance, for example.

The device is to be as light and flat as possible. This means that the layer structure with which the device is equipped must also be as light and flat as possible. Therefore, the layer structure is also to include the battery which may be necessary, which supplies power to all the electrotechnical structural elements of the layer structure. In order to facilitate the assembly of the device, the layer structure is to include only one substrate and is to form only one component. In order that the layer structure remains stable during assembly of the electrical or electrotechnical device, back injection of the layer structure is to be possible.

In order to be as unsusceptible to faults as possible and easy to clean on the surface, the layer structure is not to have moving components and is to form a continuous surface without gaps.

In order to be attractive to the user and to facilitate operation of the device, the device is to have three-dimensionally formed regions.

In order that the electrical or electrotechnical device can be supplied to a customer at the lowest possible cost, it is to be possible to produce the layer structure as simply and inexpensively as possible. Therefore, it is to be possible to produce the layer structure at least in part by means of a printing process or by spray coating. For this reason too, it is to be possible to omit electrotechnical structural elements that require expensive barrier layers against oxygen and moisture in order to function correctly.

Such devices are known in principle from the prior art. For example, switches frequently have a backlight which allows the switch, for example on a device, such as, for example, on a household appliance or a light switch in an entrance hall, to be operated even in the dark or in inadequate lighting conditions. In addition, corresponding lighting can also indicate the status of the switch, such as the “on” or “off” state. In general, a light emitting diode (LED) or a small conventional lamp is used as the light source for the backlighting of switches, the light in some cases being diffused by additional diffuser foils or so-called light-pipes or light-guides. The combination of switch and backlight is conventionally composed of at least two separate units, such as, for example, a mechanical switch and corresponding LEDs; a mechanical switch and ACPEL foils (ACPEL=alternating current powder electroluminescence) or printed switches and LEDs. These combinations known from the prior art of illuminated switches composed of separate elements have the disadvantage that they are expensive to provide and, owing to the use of mechanical components for the switch, are sensitive in terms of faults and maintenance. In addition, further disadvantages occur, such as greater weight, limited freedom in terms of form and, accordingly, design, and a greater mounting depth.

US2009/108985A1, for example, discloses a printed capacitive switch which is backlit by LEDs. However, the LEDs are not printed. US2005/0206623A1 discloses a capacitive switch which is backlit by an ACPEL foil. US2008/202912A1 discloses a capacitive switch backlit by LEDs or OLEDs (OLED=organic light emitting diode). US2007/031161A1 discloses a printed capacitive switch on a formed and back-injected plastics foil. However, this document does not disclose that the switch is backlit. However, it is known from WO98/49871A1, for example, that ACPEL foils can be printed and back injected.

ACPEL foils have the disadvantage that they require a power supply which consists of a high alternating voltage (typically 110V) at a high frequency (typically 400 Hz). A special electronic driver must be made available therefor, which generates additional costs. A further disadvantage of the combination of ACPEL foils with, for example, capacitive switches is that the power supply or triggering signals required a) for the ACPEL foil and b) for the capacitive switch interact. It is therefore necessary on the one hand to provide electromagnetic shielding between the layers so that undesired interference and associated malfunctions do not occur, and on the other hand an additional outlay is necessary in terms of the readout electronics of the capacitive switches because the interferences cannot be eliminated completely, despite electrical shielding, and the readout electronics must accordingly process noisier signals (poor signal-to-noise ratio). Furthermore, it is additionally necessary in particular to produce a dark (ACPEL foil switched on) and light (ACPEL foil switched off) logic with which the switch signals can be reliably identified because the signal-to-noise ratio of the signals of the capacitive switches that are to be evaluated differ greatly when the ACPEL foil is switched on or off. The comparatively high voltage which is necessary to operate the ACPEL foil can be dangerous for the operator in the event of a fault.

The problem of this undesirable interaction similarly arises when ACPEL foils are combined with other types of switch, for example resistive switches, or other electrotechnical structural elements which are sensitive to electromagnetic fields or waves, for example antennae or sensors.

LEDs do not have the disadvantage of this electromagnetic interaction with other electrotechnical structural elements, but they are not capable, even in combination with optical diffuser foils, of backlighting other three-dimensionally formed structural elements uniformly and without shadows because LEDs cannot be formed three-dimensionally. LEDs also increase the mounting depth of an arrangement if, in the case of the backlighting of an electrotechnical structural element, they are located beneath that element, or they require additional expensive structures such as diffuser foils or so-called light-pipes or light-guides. OLEDs and PLEDs (PLED=polymeric light emitting diode) do not have the last-mentioned disadvantage of LEDs, but OLEDs and PLEDs are extremely sensitive to oxygen and moisture. This means that they must be protected from oxygen and moisture, extremely expensively, by very high quality barrier foils or layers.

Such barrier foils or layers typically have a water vapour permeability of 10⁻⁶ g/m⁻²·day and an oxygen permeability of 10⁻⁵ cm³/m⁻²·day.

The object of the invention is, therefore, to provide a layer structure on a single substrate which has a lamp operated by means of electrical energy in combination with at least one further electrotechnical structural element.

The lamp of the layer structure is not to interact electromagnetically with the at least one further electrotechnical structural element. Also, it is to be possible to operate the lamp with a small electrical direct voltage.

The layer structure further: is to have a small thickness, is not to have moving components and is to form a continuous surface without gaps, is to be as light as possible, is to have three-dimensionally formed regions, and is to be back injectable.

The layer structure is to be simple and inexpensive to produce. It is therefore to be possible to omit electrotechnical structural elements that require very expensive barrier layers against oxygen and moisture in order to function correctly.

The object is achieved by a layer structure having the features of the main claim, namely by:
a layer structure comprising
   A) a substrate,
   B) at least one LEC (light emitting electrochemical cell) and
   C) at least one further electrotechnical structural element selected from the group consisting of antenna, switch, sensor, battery, photovoltaic cell, actuator, energy converter or combinations of two or more of those structural elements, which can be the same or different,
wherein the at least one LEC and the at least one further electrotechnical structural element are printed onto the substrate in a printing process, and the layer structure has at least one three-dimensionally formed region and/or is three-dimensionally formed as a whole.

Preferred embodiments are to be found in the dependent claims.

By using a printing process it is possible to manufacture the layer structure at low cost and in high numbers. LEC technology is particularly suitable for a printing process as compared with competing technologies.

The substrate consists substantially or wholly of a polymer selected from the group consisting of polycarbonates (PC), polyesters, preferably polyethylene terephthalates (PET), polyethylene naphthalate (PEN), polymethyl methacrylate (PMMA), polyamides, polyimides, polyarylates, organic thermoplastic cellulose esters and polyfluorohydrocarbons or mixtures of those polymers, preferably selected from polycarbonates, polyethylene terephthalates, polyethylene naphthalate and polyimides, particularly preferably selected from polycarbonates, polyethylene terephthalates and polyethylene naphthalate. Preferably, the substrate is a foil of one of the above-mentioned materials. Foil within the scope of the present invention is understood as being a substantially two-dimensional body having a thickness of from 10 μm to 1000 μm, preferably from 50 μm to 750 μm, particularly preferably from 125 μm to 500 μm. Within the scope of the invention, a substantially two-dimensional body is understood to mean that the lengths of the large surfaces are at least ten times greater than the thickness of the body, it being possible for those lengths to be the same or different.

Polycarbonates are, for example, those based on bisphenol A, in particular foils having the name Bayfol® CR (polycarbonate/polybutylene terephthalate foil), Makrofol® TP or Makrofol® DE from Bayer Material Science AG.

Polyethylene terephthalates are, for example, polyalkylene terephthalates, in particular polybutylene terephthalate.

PEN is in particular the PEN marketed under the names Kaladex® and Teonex® by DuPont Teijin Films Luxembourg S.A.

An LEC within the scope of the present invention is understood as being an electrotechnical structural element which comprises as fundamental functional parts an anode, a light emitting polymer, which can contain as additives one or more electrolytes, one or more salts or further additives, for example surfactants, and a cathode. The composition of the light emitting layer can vary. The additives can perform several functions during operation, for example they can serve as ion conductor, anion or cation. Furthermore, the additives can be functionalised and chemically crosslinked with the light emitting polymer. Finally, both metal particles having sizes in the nanometre and micrometre range and quantum dots can be dispersed into the light emitting polymer. This layer is referred to hereinbelow as the LEP layer (LEP=light emitting polymer).

The LEC can be present in various forms. In a typical form, the vertical arrangement, the anode, the LEP layer and the cathode are arranged one above the other. In an alternative arrangement, the planar arrangement, the anode, the LEP layer and the cathode can also be arranged next to one another; two opposing metal electrodes (anode, cathode) can thus be applied, for example, to a ready-printed LEP layer. The electrodes can be formed in parallel or in another form. Because the layer structure according to the invention comprises at least one LEC and an LEC comprises at least one LEP, the layer structure according to the invention consequently also comprises at least one LEP.

Moreover, pixellated illuminating segments, for example a seven-segment display, can be produced almost arbitrarily. In this manner, the LEC not only represents a lamp but also forms a display in itself.

The LEC can additionally comprise a so-called getter layer. The getter layer, where present, is preferably located on the side of the cathode that is remote from the substrate. The purpose of the getter layer is to absorb the residual moisture which can come from the individual layers or from outside. The life of the illuminating element is thereby increased. A getter layer is not absolutely necessary, however, in particular when the LEC does not need to have a long life.

The advantages of an LEC over an OLED and PLED, for example, lie in its simpler structure.

Unlike LECs, OLEDs and PLEDs have a substantially larger number of layers, for example additional hole or electron injection layers, hole or electron blocking layers, etc. Moreover, those layers require layer thicknesses in the region of a few 100 nanometres, which can be achieved only with great difficulty by means of a printing process. The thicknesses of the light emitting layers of OLEDs and PLEDs are even in the region of a few 10 nm.

The LEC, on the other hand, consists in the simplest case of three layers (anode, LEP, cathode), the thickness of the LEP layer being in the region of several hundred nanometres; in planar arrangements, the thickness can even be in the region of several millimetres, that is to say layer thicknesses which are achievable without problems by printing techniques. Furthermore, the operation of LECs is less sensitive to deviations in terms of the thickness of the LEP than is the case with OLEDs and PLEDs.

According to the invention, therefore, all the layers of the LEC are applied by a simple printing process, for example by screen printing, intaglio printing, flexographic printing, gravure printing, transfer printing, digital printing, for example ink jetprinting, or other printing processes known to the person skilled in the art, or by spray coating. These processes are simple and inexpensive, but cannot be carried out in the case of OLEDs.

Because of the way OLEDs and PLEDs operate, they require electrode materials with a suitable work function. For the cathode, for example, these consist of calcium, barium or magnesium, which are very reactive under ambient conditions and oxidise quickly. In the case of the LECs, on the other hand, a silver or aluminium electrode, for example, which is stable in terms of reactivity and oxidation is used as the cathode. This is applied according to the invention by a printing process, for example by screen printing, intaglio printing, flexographic printing, gravure printing, transfer printing, digital printing, for example ink jetprinting, or other printing processes known to the person skilled in the art, or by spray coating, while vapour deposition is typically used in the case of the OLEDs and PLEDs, which in turn requires a vacuum process. Furthermore, because of the way the LECs work, lower demands are made as regards the work function, so that an electrode material with a greater work function can be used.

Owing to the chemical stability of the layers of the LECs, these can be prepared without having to control or adjust the temperature, air pressure, atmospheric moisture or air composition, and even without the need for a protecting gas atmosphere, for example an atmosphere of pure nitrogen with a maximum water and oxygen content of in each case 0.1 ppm or of a comparably oxygen-pure and dry gas or gas mixture.

In order to ensure the long-term stability of the at least one LEC, the at least one LEC is provided with a first barrier layer on its side facing the substrate. In order to ensure this, the substrate is provided with a first barrier layer at least on one side, namely on the side facing the LEC, over its whole surface or only partially, but at least in the regions in which the at least one LEC is located. However, it is also possible for the substrate to be provided with a first barrier layer on the side that is remote from the LEC. Within the scope of the present invention, a barrier layer can be a single layer or a plurality of layers which act like a single layer in terms of their barrier properties.

The first barrier layer has a water vapour permeability of from 10⁻⁵ to 10⁻¹ g/m⁻²·day, preferably from 10⁻⁴ to 10⁻² g/m⁻²·day, particularly preferably from 10⁻⁴ to 10⁻³ g/m⁻²·day, and an oxygen permeability of from 10⁻⁵ to 10⁻¹ cm³/m⁻²·day, preferably from 10⁻⁴ to 10⁻² cm³/m⁻²·day, particularly preferably from 10⁻⁴ to 10⁻³ cm³/m⁻²·day. This barrier layer is accordingly markedly less expensive than those which are required for OLEDs and PLEDs.

The first barrier layer preferably comprises a sequence of layers of a polymeric and an inorganic layer. A polymeric layer typically consists of a photocrosslinkable monomer or polymer (e.g. acrylate). The thickness of a single polymeric layer is approximately 500 nm. An inorganic layer typically consists of metal oxides, for example of SiOₓ or Al₂O₃. The thickness of a single inorganic layer is approximately 50 nm. The first barrier layer preferably comprises from one to 10 layers; consequently, the thickness of the barrier layer can be from approximately 500 nm to approximately 6000 nm.

The individual barrier layers which are to be attributed to substrate A) can be applied by physical vapour deposition (PVD) and chemical vapour deposition (CVD) in a roll-to-roll process.

Barrier layers which can be used are disclosed, for example, in WO00/36665A1 and U.S. Pat. No. 6,268,695B1.

The substrate is further provided with an electrode layer at least on the side facing the at least one LEC, over the whole surface or only partially, in particular in the regions in which the at least one

LEC is located. The electrode layer, which for the LEC is the anode layer (anode for short), is typically approximately 100 nm thick and contains ITO (indium tin oxide), ATO (antimony tin oxide), CNTs (CNT=carbon nanotube), for example SWCNTs (SWCNT=single wall carbon nanotube), graphene or an intrinsically conductive polymer system such as, for example, PEDOT:PSS (poly(3,4-ethylenedioxythiophene) poly(styrene sulfonate)), which are marketed, for example, by H.C. Starck GmbH under the trade mark CLEVIOS and by the Agfa-Gevaert Group under the trade mark ORGACON, or polyaniline, polypyrrole or polythiophene. According to the invention, the anode layer is also applied by means of printing processes, for example by screen printing, intaglio printing, flexographic printing, gravure printing, transfer printing, digital printing, for example ink jetprinting, or other printing processes known to the person skilled in the art, or by spray coating. ITO and ATO can additionally be applied by PVD, CVD, sputtering, dip coating or by a sol-gel process. The intrinsically conductive polymers can also be applied by vacuum crosslinking.

The anode layer, provided it is correspondingly extensive, can also serve as electrode for other electrotechnical structural elements which are located on the same side of the substrate as the LEC.

If at least one further electrotechnical structural element is to be applied not only to the side of the substrate on which the at least one LEC is located, but also to the other side, both sides of the substrate can be provided with an electrode layer. It must then be ensured that the electrode layers are insulated sufficiently with respect to one another.

Moreover, substrates of polyethylene naphthalate (PEN) which are already provided on one side, over substantially the whole surface, with a first barrier layer as described above and with an anode of ITO, are offered for sale by 3M Deutschland GmbH.

The anode is in most cases transparent, so that the electroluminescent light is able to pass through it. Alternatively, the cathode can be in transparent form. In that case, the anode can be optically transparent or partly transparent.

In the planar arrangement, both the anode and the cathode can be optically non-transparent, for example can consist of thin silver or gold.

“Transparent” or “transparency” within the scope of the present invention is understood as meaning that a layer or sequence of layers in question has a transmission in the main part of the visible or IR wavelength range of the light emitted by the LEC of more than 60%, preferably more than 70%, particularly preferably more than 80%, most particularly preferably more than 90%. This is also true when the layer sequence comprises further layers not mentioned hitherto.

The getter layer, where present, is preferably located on the side of the cathode that is remote from the substrate, for example between the cathode and the one carrier layer described hereinbelow with the second barrier layer, or the metal film likewise described hereinbelow. The getter layer and the carrier layer, or metal film, can be laminated by a PSA film (PSA=pressure sensitive adhesive) or a liquid adhesive. The getter layer can be applied on the side facing the carrier layer as well as facing the cathode. It is applied according to the invention by a printing process, for example by screen printing, intaglio printing, flexographic printing, gravure printing, transfer printing, digital printing, for example ink jetprinting, or other printing processes known to the person skilled in the art, or by spray coating.

In the case of the at least one LEC, the LEP is applied to the anode layer. This is also applied according to the invention by means of printing processes, for example by screen printing, intaglio printing, flexographic printing, gravure printing, transfer printing, digital printing, for example ink-jet printing, or other printing processes known to the person skilled in the art, or by spray coating.

A further electrode layer, which for the at least one LEC is the cathode layer (cathode for short), is then applied to the LEP. The cathode layer contains silver, aluminium, copper and/or gold and is applied according to the invention by the printing of corresponding pastes, for example by screen printing, intaglio printing, flexographic printing, gravure printing, transfer printing, digital printing, for example ink jetprinting, or other printing processes known to the person skilled in the art, or by spray coating. In addition, the materials that are suitable for the anode layer are also suitable for the cathode.

The cathode layer, provided it is correspondingly extensive, can also serve as electrode for other electrotechnical structural elements which are located on the same side of the substrate as the LEC.

Suitable materials for the strip conductors which are required to supply power to the electrodes are the substances listed under the paragraphs relating to the anode and cathode. These materials can be applied by the application processes likewise listed in those paragraphs.

In order to ensure the long-term stability of the at least one LEC, the at least one LEC is provided with a second barrier layer on its side remote from the substrate. The second barrier layer can cover the substrate over its whole surface or only partially, but at least in the regions in which the at least one LEC is located.

The composition of the second barrier layer can correspond to that of the first barrier layer. The barrier layer is then applied to a carrier layer which can correspond to the substrate in terms of material and properties. The second barrier layer can be applied to the carrier layer in the same manner as the first barrier layer to the substrate.

The carrier layer with the second barrier layer is applied in such a manner that the barrier layer is located on the side of the carrier layer that faces the LEC.

Alternatively, the carrier layer with the second barrier layer can be applied in such a manner that the barrier layer is located on the side of the carrier layer that is remote from the LEC.

As an alternative to the carrier layer provided with a second barrier layer, a metal film can also be used. This has the same or better properties as the barrier layer in respect of water vapour permeability and oxygen permeability. A carrier layer is then no longer needed.

The metal film consists substantially of aluminium, gold, silver, copper, chromium and has a thickness of from 10 to 200 μm, preferably from 50 to 100 μm, particularly preferably from 60 to 80 μm. Alternatively, the metal film can be applied to the carrier layer in a corresponding manner to the barrier layer, for example by lamination, adhesive bonding or another process known to the person skilled in the art. In a further alternative embodiment, the metal film to be attributed to the substrate A) has been applied to the carrier layer by PVD processes such as, for example, sputtering.

The carrier layer with the second barrier layer, or the metal film, is joined, in particular laminated, to the LEC and optionally the other regions preferably by means of an adhesive layer, for example a PSA layer (PSA=pressure sensitive adhesive). If a getter layer is present, the adhesive layer can be introduced between the second barrier layer, to which a getter layer is applied, and the LEC. The adhesive layer can subsequently optionally be crosslinked by means of suitable UV radiation.

A further possibility for forming the adhesive layer consists in using a liquid adhesive instead of a

PSA film. The liquid adhesive is applied, for example, using a dispensing system or by means of a printing process, for example by screen printing, intaglio printing, flexographic printing, gravure printing, transfer printing, digital printing, for example ink-jet printing, or other printing processes known to the person skilled in the art, or by spray coating. The carrier layer with the second barrier layer is then correspondingly positioned over the LEC and optionally the other regions, laminated and then crosslinked by means of suitable UV radiation.

If a metal film is used as the barrier layer, the adhesive layer also forms an insulating layer with respect to the cathode.

The layer structure can additionally have the following further layers and/or components: optionally one or more insulating layers, optionally one or more protective layers, optionally one or more decorative layers, optionally one or more colour filters, optionally one or more shields, all of which are applied according to the invention by a printing process. When colour filters are used, they are to be so applied that the light of the LEC passes through them.

In order that the light of the LEC produced by the LEP layer can be emitted, the layer sequence which is applied in the emission direction, that is to say in the direction of the substrate on which the at least one LEC is applied, must be transparent. “Transparent” or “transparency” within the scope of the present invention is understood as meaning that the layer or layer sequence in question has a transmission in the main part of the visible or IR wavelength range of the light emitted by the LEC of more than 60%, preferably more than 70%, particularly preferably more than 80%, most particularly preferably more than 90%. This is also true when the layer sequence comprises further layers not mentioned hitherto.

Apart from the at least one LEC, at least one further electrotechnical structural element is applied to the substrate.

Electrotechnical structural elements are, for example, antennae, switches, sensors, batteries, accumulators (battery and accumulator are together referred to as battery hereinbelow), photovoltaic cells, actuators, that is to say systems which execute a movement or exert a mechanical force with the aid of electrical energy, energy converters, that is to say systems which convert one energy form into another. Further electrotechnical structural elements are sufficiently well known to the person skilled in the art. All the above-mentioned electrotechnical structural elements are obtainable by printing processes. Relevant publications in this connection are for antennae: US2009/066600A1; switches, sensors: US2009/0108985A1, US2007/0031161A1;

batteries: US2008/063931A1; photovoltaic cells: US2007/163638A1; actuators, energy converters: W02009/074192A1.

The at least one LEC and the at least one further electrotechnical structural element can be arranged both one above the other and next to one another relative to the surface normal of the substrate. The surface normal is a vector which is perpendicular on a plane, it being possible for the plane theoretically to be arbitrarily small. For practical considerations, the smallest unit of that plane is described for the present invention by a square of edge length 1 mm.

Where possible and necessary, the at least one further electrotechnical structural element can advantageously use the layers which are present for the structure of and the power supply to the LEC. This is true in particular for the anode layer, the cathode layer, the first barrier layer, the second barrier layer with a carrier layer, or the metal film, and the adhesive layer, as well as the electrical strip conductors and, where present, the decorative layer.

The electrical strip conductors can also connect the at least one LEC and the at least one further electrotechnical structural element together electrically. For example, the at least one LEC can be electrically connected to at least one further electrotechnical structural element selected from the group consisting of antenna, switch, sensor, battery, photovoltaic cell, actuator, energy converter or combinations of two or more of those structural elements, which can be the same or different, it also being possible for the further electrical structural elements to be connected together electrically.

If the electrical structural elements with which the LEC is connected, and which are optionally also connected together electrically, do not include a battery, then a higher-voltage power supply, that is to say a power supply which is not located on the layer structure, is necessary. Such a power supply can be, for example: the battery of the device that includes the layer structure; the battery of the product, for example a motor vehicle, in which the device is fitted; the national grid, when the layer structure is fitted, for example, into a household appliance.

Preferably, however, the layer structure comprises at least one battery which supplies power to the LEC and optionally to further electrical structural elements of the layer structure. More preferably, the layer structure comprises, in addition to the LEC and the battery, at least one further electrotechnical structural element selected from the group consisting of antenna, switch, sensor, photovoltaic cell, actuator, energy converter or combinations of two or more of those structural elements, which can be the same or different.

The at least one further electrotechnical structural element can also be provided with a barrier layer on one side or on both sides, it being possible for that/those layer(s) to be the same layer(s) as form(s) the barrier layer(s) for the LEC. It is optionally also possible for the barrier layer in the case of the at least one electrotechnical structural element to be formed by a metal film corresponding to that used in the case of the LEC.

As stated above, the layer structure as a whole can comprise the substrate, the at least one LEC, the at least one further electrotechnical structural element, it being possible for the at least one LEC and the at least one further electrotechnical structural element to be arranged both one above the other and next to one another relative to the surface normal of the substrate, the first barrier layer, the anode layer, the cathode layer, a second barrier layer with carrier layer, or a metal film, an adhesive layer and optionally further layers such as, for example, one or more insulating layers, optionally one or more protective layers, optionally one or more decorative layers, optionally one or more colour filters, optionally one or more shields. The thickness of the layer structure is from 200 μm to 3000 μm, preferably from 500 μm to 2000 μm, particularly preferably from 800 μm to 1500 μm.

In order to be attractive for the user and to facilitate operation of the device, the layer structure can have three-dimensionally formed regions. Three-dimensionally formed within the scope of the invention means that, based on the substrate of the layer structure, there is at least one surface normal on that substrate, either on the front side or on the rear side of the substrate, that is not parallel to at least one other surface normal on the same side of the substrate. Normal, production-related unevenness of the surface of the substrate, which lies within an order of magnitude of not more than +/−20 μm from the desired value of the substrate, is not taken into consideration here.

Accordingly, three-dimensionally formed means that, during at least one arbitrary step of the process for the production of the layer structure, at least one permanent forming, with regard to the substrate, has taken place relative to at least one spatial axis. Forming accordingly means not only the production of indentations or protuberances in or from a substantially flat surface but, for example, also the bending, folding or crimping of that surface.

The layer structure can be three-dimensionally formed in regions that are provided with a battery, an antenna, a switch, a sensor, a photovoltaic cell, an actuator or an energy converter. The radius of curvature of the layer structure in the formed regions can be smaller than 10 mm, preferably smaller than 5 mm, particularly preferably smaller than 2 mm, most particularly preferably smaller than 1 mm.

Preferably, however, the layer structure is provided with an indentation or protuberance having the above-mentioned radius of curvature in regions that are provided with a battery, an antenna, a switch, a sensor, a photovoltaic cell, an actuator or an energy converter.

Within the scope of the invention, the radius of curvature is determined at the midplane of the substrate.

During forming it is to be ensured that the regions of the layer structure that are provided with at least one LEC are not formed or are formed only slightly, because the barrier layers do not withstand forming as described above and their barrier properties are accordingly reduced. This leads to a reduced life of the LEC. However, forming of the layer structure as a whole−and accordingly also of the barrier layers−with a radius of curvature of 1 m and more, preferably from 2 to 10 m, particularly preferably from 3 to 5 m, is possible without damage to the barrier layer which results in a perceptible shortening of the lifetime of the LEC.

It is therefore possible, for example, for a combination of LEC and an electrotechnical structural element, for example a switch or sensor, that has a round, ellipsoid or other geometric shape when viewed from above to be so formed that there is located in the middle a switch that protrudes towards the operator, surrounded by an LEC which is flat, annular, ellipsoid-shaped at the periphery or otherwise shaped according to the periphery of the protuberance.

Alternatively, the LEC can be located flat in the middle of such a combination, while the corresponding electrotechnical structural elements follow the periphery of the LEC as protuberances.

The layer structure according to the invention is obtainable by the following process:
(1) preparation of a substrate which is provided over all or part of its surface with at least one barrier layer and with at least one anode layer;
(2) optional structuring of the at least one anode layer and optionally of electrical strip conductors;
(3) application of the at least one LEP layer to the substrate in an area that is provided both with at least one barrier layer and with at least one anode layer and in which the at least one LEC is to be formed;
(4) application of at least one cathode layer at least in the area in which the at least one LEP layer is located, and optionally of electrical strip conductors;
(5) application of an adhesive layer at least in the area in which the at least one LEC is located;
(6) application of at least one metal foil or of a second barrier layer and of a carrier layer at least in the area in which the at least one LEC is located, such that the at least one LEC is arranged between two barrier layers;
(7) application of the at least one further electrotechnical structural element;
(8) optional application of a further electrotechnical structural element or of a plurality of further electrotechnical structural elements;
   the following layers additionally being applied: one or more electrical strip conductors, optionally one or more insulating layers, optionally one or more protective layers, optionally one or more decorative layers, optionally one or more colour filters, optionally one or more shields,
   the layer structure is then three-dimensionally formed in at least one region and/or as a whole, and
   the LEP layer, the cathode layer, the adhesive layer, optionally the second barrier layer, the electrical strip conductors, the insulating layer which may be present, the protective layer which may be present and the decorative layer which may be present, as well as optionally the anode layer, are applied completely by a printing process.

In the process
(a) the steps are carried out in the indicated sequence; or
(b) step (7) and optionally step (8) are carried out at any point after step (2).

Within the context of the present invention, “structuring of the at least one electrically conductive layer” is understood as meaning that the layer or layer sequence in question is removed from the substrate, for example by chemical processes, laser ablation, punching or is covered by at least one dielectric layer, for example by the application of an insulating layer by printing, for example by screen printing, in such a manner that there remain or are left free as electrode (anode) for the at least one LEC only those regions which are necessary for the operation of the LEC and/or do not interfere with the operation of further electrotechnical structural elements of the operating system. The electrical strip conductors can optionally be structured in a corresponding manner or they can be worked from the at least one electrically conductive layer.

In order to obtain a three-dimensionally formed layer structure, the layer structure must be formed. Forming is effected, for example, by isostatic high-pressure forming, as is disclosed in EP 0 371 425 A2 and WO2009/043539 A2. Forming by thermoforming is also possible, as is disclosed in U.S. Pat. No. 5,932,167A, U.S. Pat. No. 6,210,623B1 and U.S. Pat. No. 6,257,866B1.

Both the flat, that is to say the non-formed, and the three-dimensionally formed layer structure can be back injected with a plastics material, as already disclosed in EP0371425A2 and WO2009/043539A2.

The layer structure according to the invention can be used in the production of small and large display and control elements and in the production of casing elements for mobile or stationary electronic devices or small or large household appliances or in the production of keyboard systems without moving parts.

The layer structure according to the invention is described in greater detail hereinbelow by means of exemplary embodiments for the layer sequence, wherein the features that are fundamental to the invention are to be emphasised without limiting the invention thereto.

For all the chosen examples, the LEC and the electrotechnical structural element are arranged one above the other relative to the surface normal of the substrate, and the light emitted by the LEP leaves the layer structure in the direction in which the anode is located, when viewed from the LEP. If no metal layer is present and the getter layer is absent or the getter layer is transparent, the light can leave the layer structure both in the direction of the anode and in the direction of the cathode, provided all the other layers are also transparent, which according to the invention is obligatory in the anode direction and is generally the case in the cathode direction.

### EXAMPLES

### Example 1

Shield, switch, carrier layer, barrier layer, getter layer, adhesive layer, cathode, LEP, anode, barrier layer, substrate, colour filter, decorative film.

### Example 2

Shield, switch, insulating layer, metal film, getter layer, adhesive layer, cathode, LEP, anode, barrier layer, substrate, colour filter, decorative film.

### Example 3

Carrier layer, barrier layer, getter layer, adhesive layer, cathode, LEP, anode, barrier layer, substrate, colour filter, switch, decorative film.

### Example 4

Metal film, getter layer, adhesive layer, cathode, LEP, anode, barrier layer, substrate, colour filter, switch, decorative film.

### Example 5

Carrier layer, barrier layer, adhesive layer, switch, insulating layer, getter layer, insulating layer, cathode, LEP, anode, barrier layer, substrate, colour filter, decorative film.

### Example 6

Carrier layer, barrier layer, getter layer, adhesive layer, cathode, LEP, anode, barrier layer, substrate, colour filter, adhesive layer, switch, carrier layer, decorative film.

### Example 7

Metal film, getter layer, adhesive layer, cathode, LEP, anode, barrier layer, substrate, colour filter, adhesive layer, switch, carrier layer, decorative film.

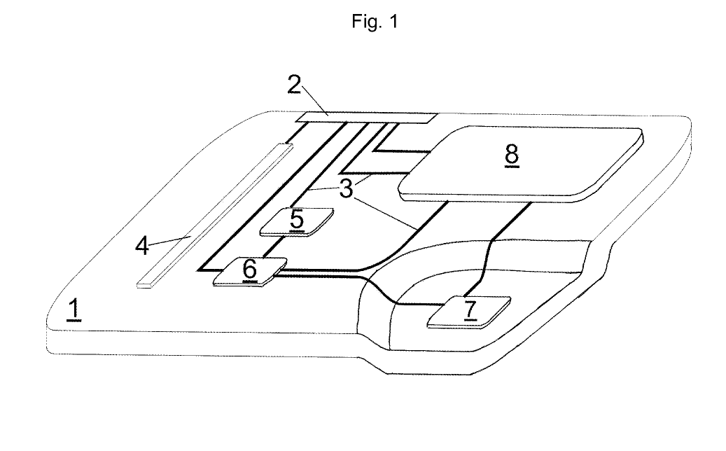

The invention is explained in greater detail hereinbelow by means of a drawing (FIG. 1); here too, the features that are fundamental to the invention are to be emphasised, without limiting the invention thereto.

FIG. 1 shows a layer structure comprising substrate 1, electrical contact plug 2, electrical connections 3, antenna 4, sensor 5, switch 6, LEC 7 and battery 8. As can be seen, the layer structure is three-dimensionally formed so that the LEC is arranged at a lower level relative to all the other components 2-6. In the present case, only electrical connections 3 are arranged at the transitions between the main level of the layer structure and the lower level of the LEC 7. However, it is also possible in principle to arrange other components in the three-dimensionally formed transition region between the lower level and the remaining level of the layer structure.

1-14. (canceled)

15. A layer structure comprising:
A) a substrate,
B) at least one light emitting electrochemical cell (LEC) and
C) at least one further electrotechnical structural element selected from the group consisting of an antenna, a switch, a sensor, a battery, a photovoltaic cell, an actuator, an energy converter and combinations of two or more of those structural elements, which can be the same or different,
wherein the at least one LEC and the at least one further electrotechnical structural element are applied to the substrate by a printing process and the layer structure has at least one three-dimensionally formed region and/or is three-dimensionally formed as a whole.

16. The layer structure of claim 15, wherein the at least one further electrochemical structural element is a battery.

17. The layer structure of claim 15, wherein the layer structure comprises at least one further electrotechnical structural element selected from the group consisting of an antenna, a switch, a sensor, a photovoltaic cell, an actuator, an energy converter and combinations of two or more of those structural elements, which can be the same or different.

18. The layer structure of claim 15, wherein the substrate comprises a polymer selected from the group consisting of polycarbonate (PC), polyester, polyethylene naphthalate (PEN), polymethyl methacrylate (PMMA), polyamide, polyimide, polyarylate, organic thermoplastic cellulose ester, polyfluorohydrocarbon and a mixture thereof.

19. The layer structure of claim 18, wherein the polymer is polycarbonate, polyethylene terephthalate, polyethylene naphthalate or polyimide.

20. The layer structure of claim 15, wherein the at least one LEC is provided with a barrier layer and an anode layer on its side facing the substrate.

21. The layer structure of claim 15, wherein the at least one LEC is provided on its side remote from the substrate with a cathode layer as well as a metal foil or a second barrier layer and a carrier layer.

22. The layer structure of claim 21, wherein the metal foil and the barrier layer with the carrier layer are being applied by means of an adhesive layer.

23. The layer structure of claim 15, wherein the layer structure has the following further layers and/or components:
an electrical strip conductor, optionally an insulating layer, optionally a protective layer, optionally a decorative layer, optionally a colour filter, optionally a shield.

24. The layer structure of claim 15, wherein the layer structure is three-dimensionally formed in at least one region, which is provided with a battery, an antenna, a switch, a sensor, a photovoltaic cell, an actuator or an energy converter.

25. The layer structure of claim 24, wherein the layer structure in the formed region has a radius of curvature of less than 10 mm.

26. The layer structure of claim 25, wherein the radius of curvature is less than 5 mm.

27. The layer structure of claim 25, wherein the radius of curvature is less than 1 mm.

28. A process for the production of the layer structure of claim 15, comprising:
(1) preparing a substrate which is provided over all or part of its surface with at least one barrier layer and with at least one anode layer;
(2) optionally structuring the at least one anode layer and optionally the electrical strip conductor;
(3) applying at least one light emitting polymer (LEP) layer to the substrate in an area that is provided both with at least one barrier layer and with at least one anode layer;
(4) applying at least one cathode layer at least in the area in which the at least one LEP layer is located, and optionally the electrical strip conductor;
(5) applying an adhesive layer at least in the area in which the at least one LEC is located;
(6) applying at least one metal foil or of a second barrier layer and of a carrier layer at least in the area in which the at least one LEC is located, such that the at least one LEC is arranged between two barrier layers;
(7) applying the at least one further electrotechnical structural element; and
(8) optionally applying of a further electrotechnical structural element or a plurality of further electrotechnical structural elements;
additionally applying the following layers: an electrical strip conductor, optionally an insulating layer, optionally a protective layer, optionally a decorative layer, optionally a colour filter,
forming a three-dimensionally layer structure in at least one region and/or as a whole, and
the LEP layer, the cathode layer, the adhesive layer, optionally the second barrier layer, the electrical strip conductor, the insulating layer which is optionally present, the protective layer which is optionally present and the decorative layer which is optionally present, as well as optionally the anode layer, are applied completely by a printing process.

29. The process according to claim 28, wherein
(a) the steps are carried out in the indicated sequence; or
(b) step (7) and optionally step (8) are carried out at any point after step (2).

30. The process according to claim 28, wherein forming is achieved by isostatic high-pressure forming or thermoforming.

31. The process according to claim 28, wherein the three-dimensionally formed layer structure is back injected.

32. A method of manufacture of an article which comprises utilizing the layer structure of claim 15, wherein the article is a display and control element, a casing element for a mobile stationary electronic device, a household appliance or a keyboard system without moving components.
